(19) United States
(12) Patent Application Publication
(10) Pub. No.: US 2013/0200075 A1
(43) Pub. Date: Aug. 8, 2013

(54) CASING

(71) Applicant: Kenji Tamura, Toyota-shi (JP)

(72) Inventor: Kenji Tamura, Toyota-shi (JP)

(21) Appl. No.: 13/741,636

(22) Filed: Jan. 15, 2013

(30) Foreign Application Priority Data
Feb. 2, 2012 (JP) 2012-021199

(51) Int. Cl. H05K 5/06

(52) U.S. Cl. CPC H05K 5/061
USPC 220/378

(57) ABSTRACT

A casing according to the invention includes: a main body that houses a housing object; a lid portion that closes the opening of the main body; and a seal member clamped between an opening edge portion of the opening and an edge portion of the lid portion. At least one of the edge portion and the opening edge portion has a recess portion that, together with a seal portion, forms a space.

### INCORPORATION BY REFERENCE

The disclosure of Japanese Patent Application No. 2012-021199 filed on Feb. 2, 2012 including the specification, drawings and abstract is incorporated herein by reference in its entirety.

### BACKGROUND OF THE INVENTION

1. Field of the Invention

The invention relates to a casing that defines an inside with respect to an outside and prevents, as much as possible, intrusion of water, such as rain water or the like, from the outside into the inside, and that has a bottomed and lidless main body that has an opening and a lid body that closes the opening of the main body.

2. Description of Related Art

Generally, electronic appliances have an electronic circuit that is contained in an inside that is defined relative to an outside by a casing. Mainly for the purposes of preventing short-circuit in the contained electronic circuit and preventing corrosion of inner surfaces of the casing, a gap between a main body and a lid portion that constitute a casing is tightly closed by a seal member such as an O-ring or the like, so that intrusion of water from the outside to the inside is prevented.

An example of such casings is a construction described in Japanese Patent Application Publication No. 2006-12877 (JP 2006-12877 A). As for the construction, it is proposed that a small gap having appropriate dimensions be formed at an outer periphery side of a seal member by an edge of the main body and an edge of the lid portion. This proposed arrangement prevents occurrence of so-called crevice corrosion based on the oxygen concentration gradient from the outside.

However, in the casing as shown in Japanese Patent Application Publication No. 2006-12877 (JP 2006-12877 A), once corrosion occurs in the small gap, the crevice corrosion progresses from the site of occurrence as a starting point, toward the inside. Thus, intrusion of water to the inside cannot be certainly prevented. Furthermore, in order to achieve formation of a small gap having appropriate dimensions, complicated shapes of the edge of the main body and the edge of the lid portion and increased external dimensions result, and stricter accuracy management is required. Furthermore, the construction requires the painting for preventing corrosion as a prerequisite. Thus, cost increase is unavoidable.

### SUMMARY OF THE INVENTION

The invention provides a casing capable of more certainly preventing intrusion of water into the inside of the casing without increasing costs.

A first aspect of the invention relates to a main body that has an opening and a first edge portion around the opening, and that houses an object to be housed; a lid portion that has a second edge portion, and that closes the opening of the main body; and a seal member clamped between the first edge portion and the second edge portion. The casing has a recess portion that defines a space between the seal member and at least one of the first edge portion and the second edge portion.

According to the invention, it is possible to more certainly prevent intrusion of water into the inside while employing a simpler production process without increasing costs.

### BRIEF DESCRIPTION OF THE DRAWINGS

Features, advantages, and technical and industrial significance of exemplary embodiments of the invention will be described below with reference to the accompanying drawings, in which like numerals denote like elements, and wherein:

FIG. 1 is a schematic diagram of an example of a casing 1 in accordance with a first embodiment of the invention;

FIG. 2 is a schematic diagram showing a detailed structure of a portion of the casing 1 of the first embodiment which clamps an O-ring 4;

FIG. 3 is a schematic diagram for illustrating a principle of occurrence of crevice corrosion that is to be prevented in embodiments of the invention;

FIG. 4 is a schematic diagram showing an example of a surface of the casing 1 of the embodiment, the surface facing a main body 2 of a lid portion 3;

FIG. 5 is a schematic diagram showing a detailed structure of a portion of a casing 1 that clamps an O-ring 4 (seal member) in accordance with a second embodiment of the invention;

FIG. 6 is a schematic diagram showing a detailed structure of a portion of a casing 1 that clamps an O-ring 4 in accordance with a third embodiment of the invention; and

FIG. 7 is a schematic diagram showing a detailed structure of a portion of a casing 1 that clamps an O-ring 4 in accordance with a fourth embodiment of the invention.

### DETAILED DESCRIPTION OF EMBODIMENTS

Embodiments of the invention will be described hereinafter with reference to the accompanying drawings.

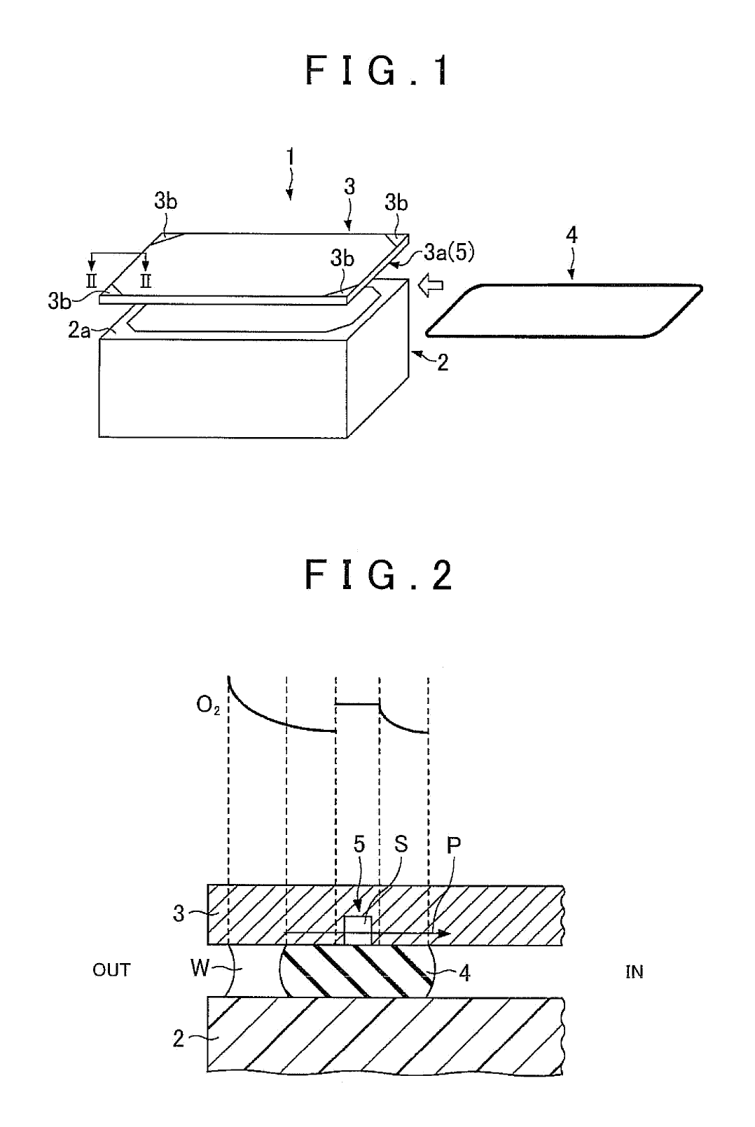

As shown in FIG. 1, a casing 1 of a first embodiment includes a main body 2 that houses an object to be housed (not shown), for example, an internal substrate of an electronic appliance, a lid portion 3 that closes an opening of the main body 2, and an O-ring 4 (seal member) clamped between an opening edge portion 2a of the opening of the main body 2 and an edge portion 3a of the lid portion 3. At least one of the edge portion 3a and the opening edge portion 2a, that is, the edge portion 3a in this example, has a recess portion 5 that, together with the O-ring 4, forms a space S.

In this example, the main body 2 has the shape of a rectangular parallelepiped with an opening and a bottom. The main body 2 is integrally molded from an electrically insulating synthetic resin. The lid portion 3 is made of, for example, an aluminum-based metal. The recess portion 5 has a square shape in a cross-section perpendicular to the direction in which the recess portion 5 extends, as shown in FIG. 2, which is a sectional view taken on line of FIG. 1. The recess portion 5 may be formed by a stamping or pressing process or by a machining or cutting process.

Incidentally, generally right-triangular corner portions 3b in the four corners of the lid portion 3 constitute fastening portions to the main body 2. The lid portion 3 is fixed to the main body 2 and the O-ring 4 is clamped between the edge portion 3a and the opening edge portion 2a by inserting male screws that correspond to female screw portions (not shown) bored in the main body 2 through a hole portion (not shown) formed in each corner portion 3b and screwing the male screws into the female screw portions.

The aforementioned internal substrate is held by a holder portion (not shown) that is grounded to an inner peripheral surface of the main body 2. The wirings for sending and receiving signals to and from other appliances (not shown) as well as for power distribution and grounding purposes are integrated into a connector (not shown). This connector is inserted through and fixed to the lid portion 3 and the main body 2 in a liquid-tight manner at an appropriate location by an appropriate measure.

The recess portion 5 has a hollow annular shape having a narrower width than the O-ring 4, and extends on a quadrilateral closed curve line located substantially in the middle between an outside OUT of the casing 1 and an inside IN of the casing 1. The space S formed by the recess portion 5 and the O-ring 4 is liquid-tightly defined with respect to both the outside OUT and the inside IN of the casing 1 by the O-ring 4.

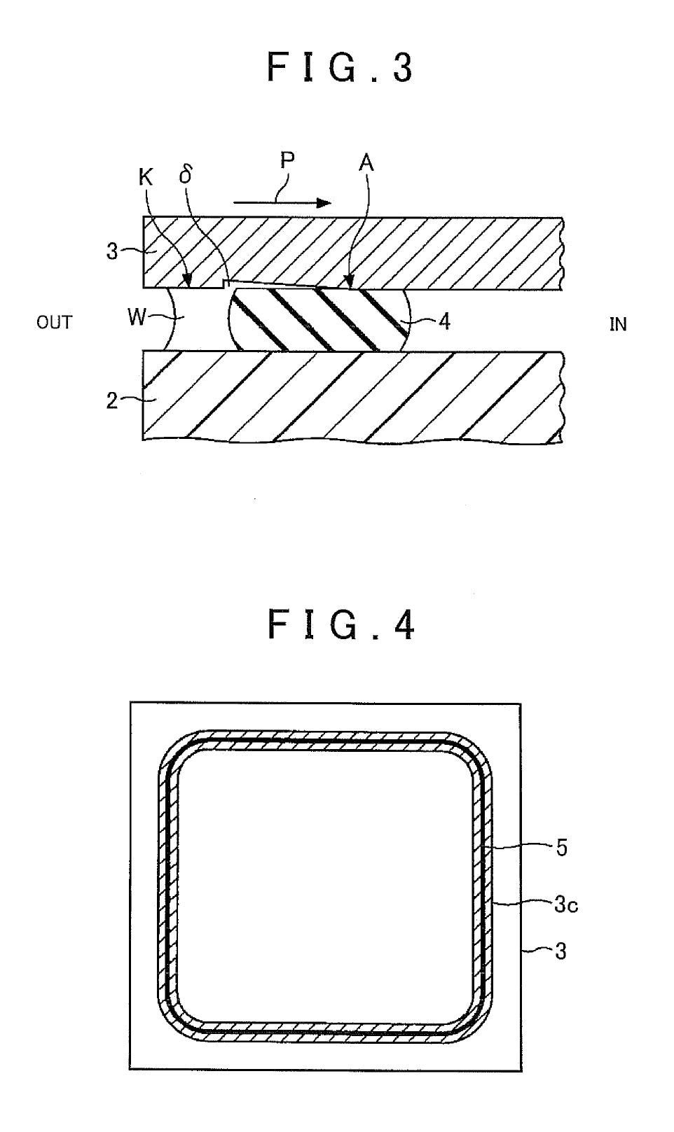

Now, a form of development of so-called crevice corrosion in a construction shown in FIG. 3 that does not include a recess portion 5 will be described. In the case where water W, such as rain water or the like, adheres on the outer side of the O-ring 4 in the gap between the main body 2 and the lid portion 3, there occurs difference in the concentration of O₂ (oxygen) contained in the water W between an outer-side location K and a location A that is inwardly of the location K in the direction P from the outside OUT to the inside IN. That is, the water W has higher O₂ concentrations at the outside OUT, that is, the O₂ concentration is lower at the. location A than at the location K.

When the O₂ concentration varies in the direction P in this manner, the locations K and A form electrodes, that is, the location K, which is higher in the O₂ concentration, becomes a cathode, and the location A, which is lower in the O₂ concentration, becomes an anode. That is, a cathode reaction of 2H⁺+2e⁻→H₂ occurs at the location K, and an anode reaction of Al→Al³⁺+3e⁻ occurs at the location A. Due to the anode reaction, Al³⁺ ions dissolve from the lid portion 3, and thus corrosion occurs. When this ionization occurs, a gap 8 between the O-ring 4 and the lid portion 3 shown in FIG. 3 undergoes erosion due to the corrosion, and gradually enlarges into a wedge shape that is higher (or deeper into the lid portion 3) at a side closer to the outside OUT. As this ionization repeatedly or continually occurs, the corrosion develops in the direction P.

In contrast, in the first embodiment, since the space S is formed by the recess portion 5 at an intermediate location in the direction P as shown in FIG. 2, there exists a state in which air contained in the space S at the time of fixing the lid portion 3 to the main body 2 remains in the space S. Therefore, when the water W exits in the gap between the main body 2 and the lid portion 3, the O₂ concentration in the water W, which gradually decreases from the outside OUT toward the inside IN in the direction P, rises at the location of the space S to substantially cancel the O₂ concentration decrease (i.e., reduce the concentration difference) as the water W contacts air in the space S, as shown in an upper portion of FIG. 2. Incidentally, the O₂ concentration curve shown in FIG. 2 is merely illustrative.

Therefore, the location where the anode forms is shifted to a position outside the space S (i.e., shifted toward the outside OUT), so as to restrain, as much as possible, formation of an anode at the location A closer to the inside IN, and thereby restraining occurrence of ionization at the location A. That is, even if the crevice corrosion progresses in the direction P from the outside OUT by the mechanism shown in FIG. 3, the progress of the crevice corrosion in the direction P can be stopped at the space S. Thus, intrusion of water from the outside OUT into the inside IN can be more certainly prevented.

Furthermore; it suffices that the recess portion 5 has a dimensional relationship with the O-ring 4 which is required in order for the recess portion 5 and the O-ring 4 to form the space S, that is, the recess portion 5 has a width that is sufficiently smaller than the diameter of the cross-sectional shape of the O-ring 4. Therefore, this design does not result in a complicated shape of the edge portion 3a of the lid portion 3, and does not result in stricter accuracy management of the edge portion 3a.

Furthermore, what is required in the first embodiment is merely that the annular recess portion 5 be provided at an intermediate location in the direction Pin a contact surface 3c of the lid portion that contacts the O-ring 4, as shown in FIG. 4. Therefore, increased external shape dimensions of the lid portion 3 and the main body 2 do not result. Further, since corrosion prevention can be carried out by devising a shape, it is possible to omit a painting process or a chemical coating process for the purpose of preventing corrosion of the contact surface 3c of the lid portion 3 which contacts the O-ring 4. That is, according to the first embodiment, it is possible to accomplish corrosion prevention while reducing costs.

Although in the foregoing embodiment, the main body 2 is made of synthetic resin, the main body 2 may also be made of an aluminum-based metal. In that case, the lid portion 3 and the main body 2 may be electrically interconnected at an appropriate site, and may be connected to a ground wire, and a recess portion that corresponds to the above-described recess portion 5 may be provided in the opening edge portion 2a of the main body 2. This construction will prevent progress of crevice corrosion on the main body 2 side as well.

Although the first embodiment has been described above in conjunction with a configuration in which the recess portion 5 has one recess strip in the direction P from the outside OUT to the inside IN, the recess portion may include a plurality of recess strips, that is, a plurality of recess portions 5 may be provided. With this respect, a second embodiment of the invention will be described below.

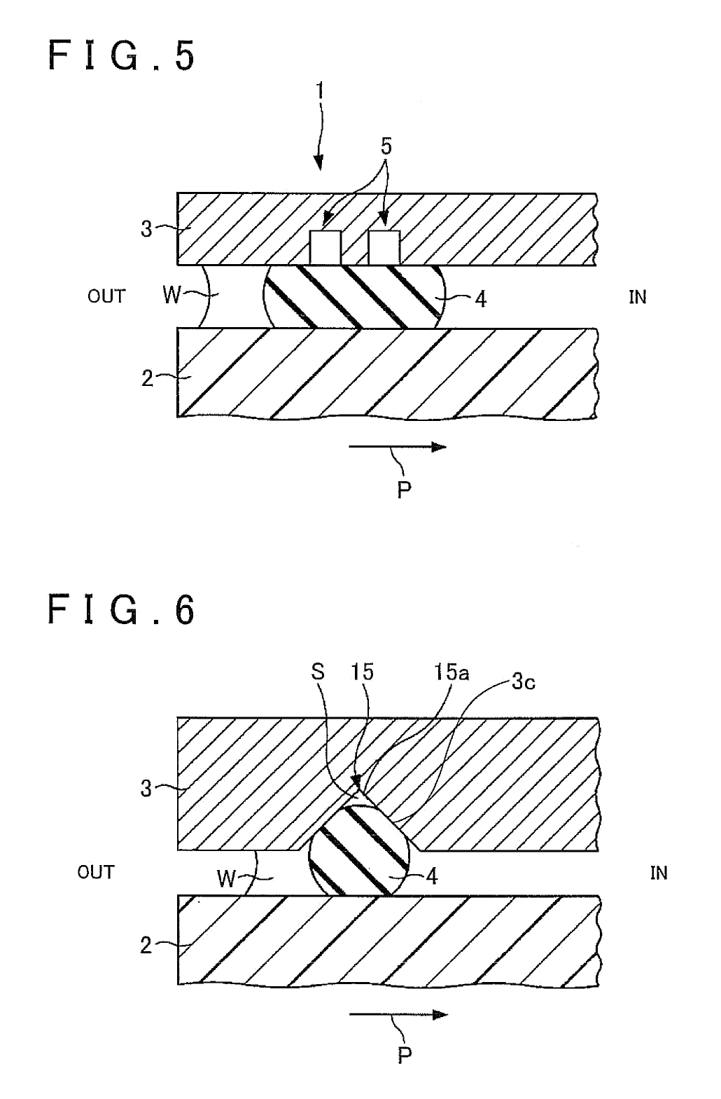

As shown in FIG. 5, a casing 1 in accordance with the second embodiment is provided with a recess portion 5 that has two recess strips (hereinafter, termed the two recess portions 5) in the direction P from the outside OUT to the inside IN. The cross-sectional shape of each of the two recess portions 5 is a square shape as in the first embodiment. The two recess portions 5 are juxtaposed with an interval therebetween in the direction P.

According to the casing 1 of the second embodiment, the gradual decrease of the O₂ concentration in the water W from the outside OUT toward the inside IN can be cancelled twice (or at two locations) in the direction P as the water W contacts the air contained in each of the two recess portions 5 and therefore the O₂ concentration in the water W increases in such a manner.

That is, as the O₂ concentration difference in the direction P is further lessened, it is possible to prevent, as much as possible, the electrodes of a concentration cell from being formed at the location K at the outside OUT and the location A at the inside IN in the P direction. That is, at the location A side, a member that constitutes the lid portion 3 can be prevented from ionizing and therefore progress of corrosion can be prevented.

Although in the foregoing embodiments, the cross-sectional shape of the recess portions 5 is a square shape, other sectional shapes may also be adopted. That is, in the case where the lid portion 3 is pressed against the O-ring 4 by utilizing the force for fixing the lid portion 3 to the main body 2, the cross-sectional shape of the recess portions 5 may be any shape, for example, an arc shape, a shape whose opening width is smaller than a width of the opening at a greater depth in the opening, or the like, as long as the cross-sectional shape of the recess portions 5 is such a shape that liquid tightness is achieved with respect to both the outside OUT and the inside IN. Incidentally, with regard the shape of the recess portion, other shapes may also be adopted by taking into account the conveniences in conjunction with a die casting process of the lid portion 3. With that respect, a third embodiment will be described below.

In the third embodiment, a recess portion 15 has a V shape whose width gradually decreases from the opening side to a deep end side as shown in FIG. 6. That is, the shape of a cross section of the recess portion 15 perpendicular to the direction in which the recess portion 15 extends is a triangular shape. A space S is provided in a V-shaped corner portion 15a of the recess portion 15 which is a deep end portion of the V-shaped recess portion 15 which the O-ring 4 does not reach when the lid portion 3 and the main body 2 are fastened together so that the O-ring 4 is clamped between the opening edge portion 2a of the main body 2 and the edge portion 3a of the lid portion 3. In the third embodiment, the contact surface 3c as shown in FIG. 4 is fanned by slope surfaces of the V-shaped recess portion 15.

In the third embodiment, the gradual decrease of the O₂ concentration in the water W from the outside OUT toward the inside IN is cancelled as the water W contacts the air contained in the recess portion 15, that is, in the space S and therefore the O₂ concentration increases at that location. That is, as in the first embodiment, it is possible to prevent, as much as possible, the electrodes of a concentration cell from being formed at the location K at the outside OUT and the location A at the inside IN in the P direction. Therefore, at the location A side, a member that constitutes the lid portion 3 can be prevented from ionizing and therefore progress of corrosion can be prevented.

In addition, in the third embodiment, the recess portion 15 has a V shape, which is more convenient to form the recess portion 15 in a die casting process. That is, a casting process for forming the recess portion 15 using a protruded portion of a die is made easier, and the release of the die after the casting process is also made easier.

Incidentally, the die casting process is a process in which, for example, a high-precision die is made from a special steel and the die is attached to a die casting machine, and in which a molten aluminum-based metal is injected at high pressure into the die, and is rapidly solidified, and is taken out of the die, and this process is one of the casting methods that are more advantageous in seeking higher productivity.

Furthermore, in the third embodiment, since the slope surfaces of the V-shaped recess portion 15 are pressed against the O-ring 4, there can be achieved an effect of clamping the O-ring 4 not only in the direction in which the lid portion 3 presses the O-ring 4 against the main body 2 but also in the direction P from the outside OUT to the inside IN. Therefore, the characteristic of the sealing between the O-ring 4 and the contact surface 3c can be improved.

Although in the third embodiment, the V-shaped recess portion 15 has one recess strip if it is counted in the direction P, the recess portion 15 may also be provided with two or more recess strops, that is, a plurality of recess portions 15 may also be provided. Furthermore, recess portions 15 may partially overlap with each other in the direction P so as to form a shape that combines two triangles. In that respect, a fourth embodiment will be described.

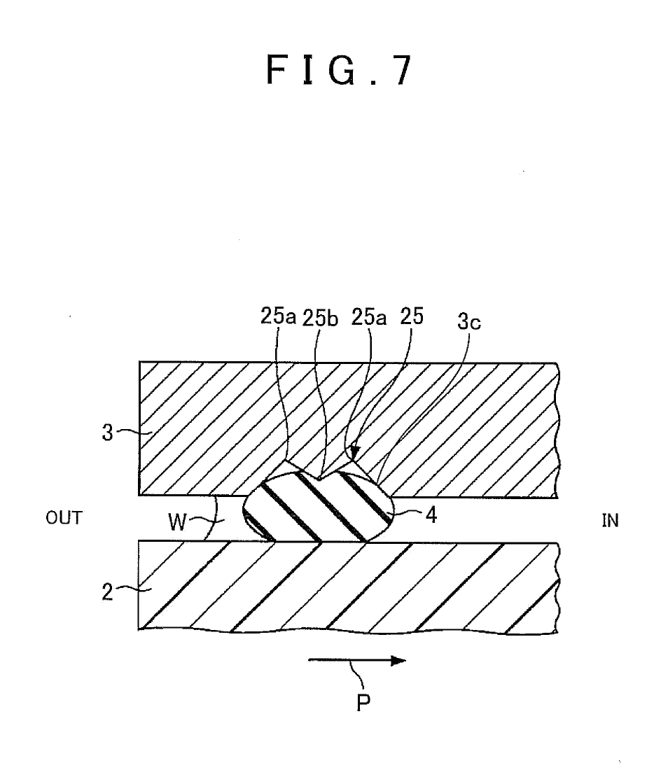

In the fourth embodiment, as shown in FIG. 7, a recess portion 25 has a W shape (bellows shape) that combines two V shapes each of which becomes gradually smaller in width from the opening side. That is, the shape of a cross section of the recess portion 25 perpendicular to the direction in which the recess portion 25 extends is a shape combining two triangular shapes.

Space portions S are provided in two V-shaped corner portions 25a of the recess portion 25 which the O-ring 4 does not reach when the lid portion 3 is fastened to the main body 2 so that the O-ring 4 is clamped between the opening edge portion 2a of the main body 2 and the edge portion 3a of the lid portion 3. In the fourth embodiment, three contact-area strips that contact the O-ring 4 are formed by the four slope wall surfaces of the W-shaped recess portion 25, and two strip spaces S are formed in the intervals between the three contact-area strips in the direction P.

In the fourth embodiment, the gradual decrease of the O₂ concentration in the water W from the outside OUT toward the inside IN is cancelled as the water W contacts the air contained in the recess portion 25, that is, in each of the spaces S and therefore the O₂ concentration increases accordingly. In this fourth embodiment, the cancellation of the O₂ concentration decrease is performed twice, that is, at two locations.

That is, it is possible to prevent, as much as possible, the electrodes of a concentration cell from being formed at the location K at the outside OUT and the location A at the inside IN in the P direction. Therefore, at the location A side, a member that constitutes the lid portion 3 can be prevented from ionizing and therefore progress of corrosion can be prevented.

In addition, in the fourth embodiment, the recess portion 25 has a W shape, which is more convenient to form the recess portion 25 in a die casting process. That is, a casting process for forming the recess portion 25 using a protruded portion of a die is made easier, and the release of the die after the casting process is also made easier.

Furthermore, in the fourth embodiment, the W-shaped recess portion 25 includes four slope surfaces, and two of the slope surfaces that are located intermediately in the direction P are provided with a smaller slope angle than the other two slope surfaces, that is, the outermost and innermost slope surfaces. Since these slope surfaces and a projected portion 25b located intermediately between the corner portions 25a in the direction P are pressed against the O-ring 4, there can be achieved both the effect of clamping the O-ring 4 not only in the direction in which the lid portion 3 presses the O-ring 4 against the main body 2 but also in the direction P from the outside OUT to the inside IN and an effect of pressing the projected portion 25b into the O-ring 4. Therefore, the characteristic of the sealing between the O-ring 4 and the contact surface 3c can be further improved.

Furthermore, the W shape is formed by an arrangement in which two V shapes are overlapped with each other in the direction P with the slope surfaces provided as described above. Therefore, if the projected portion 25b is projected to a recessed position relative to the main body 2-facing flat surface of the lid portion and is projected so as to have a slightly obtuse angle, it is possible to avoid excessively pressing the projected portion 25b into the O-ring 4 and therefore avoid impairment of the endurance of the O-ring 4 while achieving certain effect of the projected portion 25b digging into the O-ring 4.

While what are considered to be preferred embodiments of the invention have been described above, the invention is not restricted by the foregoing embodiments. On the contrary, the foregoing embodiments can be modified in various manners and with various replacements.

For example, although in the foregoing embodiments, the material of the casing to be prevented from rusting is an aluminum-based material, the invention can be applied to any other material if the material is subject to corrosion due to ionization based on the above-stated principle of a concentration cell.

The invention relates to a casing that requires prevention of intrusion of water from the outside into the inside of the casing, and allows cost reductions since the invention does not require either complicated structures of the edge and its vicinity of each of the main body and the lid portion that constitute the casing or complicated production processes, and does not require stricter management of dimension accuracy, and allows a painting or coating process to be omitted.

Therefore, the invention is generally applicable to casings of electronic appliances that house internal substrates, and is particularly useful in application to casings of electronic appliances that are mounted in various vehicles, such as passenger cars, trucks, busses, etc. which strongly require prevention of intrusion of rain water and need consideration of salt damage.

What is claimed is:

1. A casing comprising:
a main body that has an opening and a first edge portion around the opening, and that houses an object to be housed;
a lid portion that has a second edge portion, and that closes the opening of the main body;
a seal member clamped between the first edge portion and the second edge portion; and
a recess portion that defines a space between the seal member and at least one of the first edge portion and the second edge portion.

2. The casing according to claim 1, wherein
the space is liquid-tightly defined relative to both an outside of the casing and an inside of the casing by the seal member.

3. The casing according to claim 2, wherein
a shape of a section of the recess portion perpendicular to a direction in which the recess portion extends is square or rectangular.

4. The casing according to claim 3, wherein
a plurality of the recess portions are provided in a direction from an outer side of the first edge portion to an inner side of the first edge portion.

5. The casing according to claim 2, wherein
a shape of a section of the recess portion perpendicular to a direction in which the recess portion extends is triangular.

6. The casing according to claim 2, wherein
a shape of a section of the recess portion perpendicular to a direction in which the recess portion extends is a shape combining two or more triangular shapes.

7. The casing according to claim 5, wherein
a plurality of the spaces are provided in a direction from an outer side of the first edge portion to an inner side of the first edge portion.

8. The casing according to claim 1, wherein
at least one of the main body and the lid portion is made of metal.
